(19) United States
(12) Patent Application Publication
(10) Pub. No.: US 2016/0190422 A1
(43) Pub. Date: Jun. 30, 2016

(54) THERMOELECTRIC CONVERSION MATERIAL, MANUFACTURING METHOD OF THE SAME, AND THERMOELECTRIC CONVERSION DEVICE USING THE SAME

(71) Applicants: TOYOTA JIDOSHA KABUSHIKI KAISHA, Toyota-shi (JP); Admatechs Company Limited, Miyoshi-shi (JP)

(72) Inventors: Junya MURAI, Nissin-shi (JP); Tomonari KOGURE, Toyota-shi (JP); Youichiro KAWAI, Okazaki-shi (JP); Yoshinori Okawauchi, Nagoya-shi (JP)

(73) Assignees: TOYOTA JIDOSHA KABUSHIKI KAISHA, Toyota-shi (JP); Admatechs Company Limited, Miyoshi-shi (JP)

(21) Appl. No.: 14/978,818

(22) Filed: Dec. 22, 2015

(30) Foreign Application Priority Data
Dec. 26, 2014 (JP) 2014-263871
Sep. 4, 2015 (JP) 2015-174689

(51) Int. Cl. H01L 35/34; H01L 35/16; H01L 35/22; H01L 35/18

(52) U.S. Cl. CPC H01L 35/34; H01L 35/18; H01L 35/16; H01L 35/22

(57) ABSTRACT

A BiTe-based or CoSb₃-based thermoelectric conversion material includes a base phase material in which an oxide layer is formed on a surface of the base phase, in which the thermoelectric conversion material is manufactured by a method including (a) a weak oxidizing process selected from (a1) mixing base phase material powders under a low-oxygen atmosphere and thereafter exposing the base phase material powders to the low-oxygen atmosphere, and (a2) impregnating base phase material powders with alcohol, and (b) an alloying process of performing a heat treatment on a powder obtained in the process (a1) or a solution obtained in (a2), and the processes (a) and (b) are continuously performed.

### INCORPORATION BY REFERENCE

The disclosure of Japanese Patent Application Nos. 2014-263871 and 2015-174689 filed on Dec. 26, 2014 and Sep. 4, 2015 including the specification, drawings and abstract is incorporated herein by reference in its entirety.

### BACKGROUND OF THE INVENTION

1. Field of the Invention

The present invention relates to a thermoelectric conversion material, a manufacturing method of the same, and a thermoelectric conversion device using the same.

2. Description of Related Art

In recent years, in order to reduce carbon dioxide emissions due to global warming, there has been an increasing interest in techniques for reducing the fossil fuel energy consumption. As one of such techniques, a thermoelectric conversion material capable of directly converting waste heat energy that is not used into electrical energy, and a thermoelectric conversion device using the same are suggested. A thermoelectric conversion material is a material which enables the direct conversion of heat into electrical energy without the use of a process having two stages of temporarily converting heat into kinetic energy and then converting it into electrical energy, like thermal power generation.

The conversion of heat into electrical energy is achieved by using a temperature difference between both ends of a bulk body formed from the thermoelectric conversion material. The phenomenon in which a voltage is generated by the temperature difference was discovered by Seebeck and is called the Seebeck effect. The performance of the thermoelectric conversion material is expressed as the figure of merit Z obtained by the following expression.

Z=α²σ/κ(=Pf/K)

Where α is the Seebeck coefficient of the thermoelectric conversion material, σ is the conductivity of the thermoelectric conversion material, and K is the thermal conductivity of the thermoelectric conversion material. The term α²σ is collectively referred to as an output factor Pf. Here, Z has the dimension of the reciprocal of a temperature, and ZT, which is obtained by multiplying the figure of merit Z by an absolute temperature T, becomes a dimensionless value. In addition, ZT is called a dimensionless figure of merit and is used as an index representing the performance of the thermoelectric conversion material. Therefore, as is apparent from the above expression, a lower thermal conductivity κ is required for the enhancement of the performance of the thermoelectric conversion material.

There is a problem that grain sizes are coarsened due to heating or long-term use in a manufacturing process and the thermal conductivity is not reduced.

For example, in Japanese Patent Application Publication No. 2001-250990 (JP 2001-250990 A), a thermoelectric material in which the average grain size of crystal grains is restricted to 50 μm or smaller and the oxygen content is restricted to 1500 ppm or lower by mass, and a manufacturing method of the same are described. An object of JP 2001-250990 A is to solve the problems of the manufacturing method in which the specific resistance ρ of the thermoelectric material is increased due to oxide films formed on the surface of powder. According to JP 2001-250990 A, it is considered that by removing the oxide films formed at the grain boundary of the powder through reduction during the manufacturing of the thermoelectric material, the specific resistance ρ of the thermoelectric material is reduced, and thus the figure of merit Z of the thermoelectric material can be enhanced. Specifically, as the manufacturing method, it is described that a raw material containing the elements Bi, Te, and the like is formed into a thinner film shape by a liquid quenching method, is formed into powder, and is thereafter heated to reduce the powder, and the resultant is then subjected to a sintering treatment. However, in a case where the raw material is refined by the liquid quenching before the heat treatment, there is a problem in that the crystal size of the base material is coarsened due to the subsequent heat treatment.

Therefore, a thermoelectric conversion material having excellent electrical characteristics, particularly low electrical resistance, and sufficiently reduced thermal conductivity, and a simple manufacturing method of the thermoelectric conversion material are required.

### SUMMARY OF THE INVENTION

The present invention provides a thermoelectric conversion material which enables excellent electrical characteristics and thermal conductivity, and a simple manufacturing method of the thermoelectric conversion material. In addition, the present invention provides a thermoelectric conversion device using the thermoelectric conversion material.

The inventors found that, by manufacturing a BiTe-based or CoSb₃-based thermoelectric conversion material using a method including specific processes, excellent electrical characteristics, particularly low electrical resistance, and sufficiently reduced thermal conductivity can be obtained. In this method, the oxidation of raw material powders are performed before alloying the raw material powders, and thus the coarsening of alloy crystals is impeded by oxides during the alloying (pinning effect). Therefore, a thermoelectric conversion material having fine crystals can be obtained. The thermoelectric conversion material obtained in this method has a relatively small amount of oxides and thus has high electrical conductivity. In addition, since the crystals are fine, good properties of low lattice thermal conductivity are exhibited. Furthermore, the inventors found that the BiTe-based or CoSb₃-based thermoelectric conversion material can be easily manufactured by continuously performing the specific processes.

According to a first aspect of the present invention, there is provided a BiTe-based or CoSb₃-based thermoelectric conversion material including a base phase material in which an oxide layer is formed on a surface of the base phase.

The thermoelectric conversion material is manufactured by a method including (a) a weak oxidizing process selected from (a1) mixing base phase material powders under a low-oxygen atmosphere and thereafter exposing the base phase material powders to the low-oxygen atmosphere, and (a2) impregnating base phase material powders with alcohol, and (b) an alloying process of performing a heat treatment on a powder obtained in the process (a1) or a solution obtained in (a2), and the processes (a) and (b) are continuously performed.

An average grain size of crystal grains of the base phase material may be 400 nm or smaller, a thickness of the oxide layer may be 0.1 nm to 10 nm, the oxide layer may have an average minor axis r of 2 nm to 15 nm and an average major axis R of 10 nm to 500 nm, and r and R may satisfy the expression: r≦R.

A total oxygen content of the thermoelectric conversion material may be 0.05 wt % to 0.5 wt % with respect to a weight of the thermoelectric conversion material.

According to a second aspect of the present invention, there is provided a manufacturing method of a BiTe-based or CoSb₃-based thermoelectric conversion material, including: (a) a weak oxidizing process selected from (a1) mixing base phase material powders under a low-oxygen atmosphere and thereafter exposing the base phase material powders to the low-oxygen atmosphere, and (a2) impregnating the base phase material powders with alcohol; and (b) an alloying process of performing a heat treatment on a powder obtained in the process (a1) or a solution obtained in (a2), in which the processes (a) and (b) are continuously performed.

According to a third aspect of the present invention, there is provided a thermoelectric conversion device using the thermoelectric conversion material.

According to the BiTe-based or CoSb₃-based thermoelectric conversion material of the present invention, sufficiently low thermal conductivity can be achieved while suppressing an increase in electrical resistance due to the introduction of oxides. According to the manufacturing method of a BiTe-based or CoSb₃-based thermoelectric conversion material of the present invention, the BiTe-based or CoSb₃-based thermoelectric conversion material described above can be manufactured in simple processes and thus a reduction in costs and scale-up are enabled.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a transmission electron microscope (TEM) image of a thermoelectric conversion material (after sintering) of Example 1-1;

FIG. 2 is a TEM image of the thermoelectric conversion material (after sintering) of Example 1-1;

FIG. 3 is a scanning electron microscope (SEM) image of a thermoelectric conversion material before sintering is performed after a heat treatment is performed in a method described in Example 2;

FIG. 4 is a TEM image of the thermoelectric conversion material (after sintering) of Example 2;

FIG. 5 is a TEM image of a thermoelectric conversion material before sintering is performed after a heat treatment is performed in a method described in Comparative Example 1;

FIG. 6A is a graph showing the total oxygen content of the thermoelectric conversion materials of Examples 1 and 2, Comparative Examples 1 and 2, and Reference Example 1, and the average grain size of crystal grains (average crystal grain size) of the base phase material thereof;

FIG. 6B is an enlarged graph of a portion of FIG. 6A;

FIG. 7A is a graph showing the total oxygen content of the thermoelectric conversion materials of Examples 1 and 2, Comparative Examples 1 and 2, and Reference Example 1, and the lattice thermal conductivity thereof;

FIG. 7B is a graph showing the total oxygen content and the specific resistance of the thermoelectric conversion materials of Examples 1 and 2, Comparative Examples 1 and 2, and Reference Example 1; and

FIG. 7C is a graph showing the lattice thermal conductivity and the specific resistance of the thermoelectric conversion materials of Examples 1 and 2, Comparative Examples 1 and 2, and Reference Example 1.

### DETAILED DESCRIPTION OF EMBODIMENTS

A BiTe-based or CoSb₃-based thermoelectric conversion material of an embodiment of the present invention (hereinafter, also referred to as a thermoelectric conversion material of the present invention), includes a base phase material in which an oxide layer is formed on the surface, and is manufactured by a method including (a) a weak oxidizing process selected from (a1) mixing base phase material powders under a low-oxygen atmosphere and thereafter exposing the base phase material powders to the low-oxygen atmosphere, and (a2) impregnating base phase material powders with alcohol, and (b) an alloying process of performing a heat treatment on a powder obtained in the process (a1) or a solution obtained in (a2), in which the processes (a) and (b) are continuously performed.

By manufacturing the thermoelectric conversion material according to the method, the base phase material and the oxide layer having preferable features and properties for achieving low electrical resistance and sufficiently reduced thermal conductivity can be formed. By manufacturing the thermoelectric conversion material according to the method, even when the oxide layer has low oxygen content, the oxide layer exhibits a pinning effect on the base phase material, that is, an effect of interrupting grain coarsening of the base phase material due to heating in the manufacturing process, thereby suppressing an increase in thermal conductivity. In a case of low oxygen content, an increase in electrical resistance can be suppressed. In addition, it is thought that the pinning effect is maintained even in long-term use at high temperatures. Regarding the above-mentioned processes, the manufacturing method of the thermoelectric conversion material of the embodiment of the present invention will be described.

The base phase material contained in the thermoelectric conversion material of the embodiment of the present invention is a BiTe-based or CoSb₃-based material. As the BiTe-based material, specifically, any of (Bi, Sb)₂Te₃-based, (Bi, Sb)₂(Te, Se)₃-based, Bi₂Te₃-based, (Bi, Sb)Te-based, and Bi(Te, Se)-based materials may be appropriately employed. The BiTe-based and CoSb₃-based materials have a common characteristic of being nanocrystallized by a hydrothermal treatment, and it can be expected that both the BiTe-based and CoSb₃-based materials exhibit the same effect as the thermoelectric conversion material.

The BiTe-based or CoSb₃-based thermoelectric conversion material may include the base phase material having a specific average grain size and the oxide layer having a specific shape and a size.

In the thermoelectric conversion material, the average grain size of crystal grains (hereinafter, also referred to as average crystal grain size) of the base phase material may be 400 nm or smaller. As the crystal grains of the base phase material are refined (nanocrystallized), an increase in thermal conductivity can be suppressed, and the thermal conduction properties are enhanced. From this viewpoint, the average crystal grain size thereof is preferably 10 nm to 400 nm, more preferably 10 nm to 300 nm, and preferably 10 nm to 200 nm. The average crystal grain size is expressed as a value after a sintering treatment.

The average crystal grain size can be calculated by obtaining a grain size distribution from an image obtained by using a scanning electron microscope (SEM) or a transmission electron microscope (TEM). However, the thermoelectric conversion material which is defocused is excluded from a measurement object. The average crystal grain size before the sintering treatment is performed, is 0.2 times to 1 times, and preferably 0.5 times to 1 times the value after the sintering.

Oxides of the oxide layer are oxides of the BiTe-based or CoSb₃-based base phase material, and specifically, oxides containing Bi, Te, Sb, or Se, such as Sb₂O₃, Bi₂O₃, Bi₂TeO₅, BiSbO₄, Te0₃, or SeO₂ may be employed.

From the viewpoint of holding electrical conduction properties, the thickness of the oxide layer is preferably 0.1 nm to 10 nm, more preferably 0.3 nm to 10 nm, and particularly preferably 0.5 nm to 5 nm. The thickness of the oxide layer is expressed as a value after the sintering treatment. The thickness of the oxide layer can be determined from a TEM image as described below in “2. TEM observation”.

The average minor axis r of the oxide layer is preferably 2 nm to 15 nm from the viewpoint of specific surface area. The average minor axis r of the oxide layer is expressed as a value after the sintering treatment. The average minor axis r of the oxide layer can be determined from a TEM image as described below in “2. TEM observation”.

The average major axis R of the oxide layer is preferably 10 nm to 500 nm, more preferably 10 nm to 100 nm, and particularly preferably 10 nm to 50 nm, from the viewpoint of specific surface area. The average major axis R of the oxide layer is expressed as a value after the sintering treatment. The average major axis R of the oxide layer can be determined from a TEM image as described below in “2. TEM observation”.

In an embodiment of the thermoelectric conversion material of the present invention, the thickness of the oxide layer is 0.1 nm to 10 nm, the average minor axis r of the oxide layer is 2 nm to 15 nm, the average major axis R thereof is 10 nm to 500 nm, and r and R satisfy the expression: r≦R.

From the viewpoint of suppressing an increase in electrical resistance, it is preferable that the total oxygen content of the thermoelectric conversion material is 0.05 wt % to 0.5 wt % with respect to the weight of the thermoelectric conversion material. The total oxygen content of the oxide layer is expressed as a value after the sintering treatment.

From the viewpoint of enhancing the performance of the thermoelectric conversion material, the lattice thermal conductivity of the thermoelectric conversion material is preferably 0.50 W/m/K or lower, more preferably 0.35 W/m/K or lower, and particularly preferably 0.30 W/m/K or lower.

From the viewpoint of enhancing the performance of the thermoelectric conversion material, the specific resistance of the thermoelectric conversion material is preferably 20 μΩm or lower, and more preferably 15 μΩm or lower.

A manufacturing method of the embodiment of the present invention includes: (a) a weak oxidizing process selected from (a1) mixing base phase material powders under a low-oxygen atmosphere and thereafter exposing the base phase material powders to the low-oxygen atmosphere, and (a2) impregnating base phase material powders with alcohol; and (b) an alloying process of performing a heat treatment on a powder obtained in the process (a1) or a solution obtained in (a2), in which the processes (a) and (b) are continuously performed. This manufacturing method is constituted by extremely simple processes, and a BiTe-based or CoSb₃-based thermoelectric conversion material having low electrical resistance and sufficiently reduced thermal conductivity can be obtained.

<Weak Oxidizing Process>

In the process (a), only the surface of the base phase material powders are oxidized to a predetermined degree. From the viewpoint of suppressing an increase in electrical resistance, it is preferable that the oxidizing is performed so that the total oxygen content of the obtained thermoelectric conversion material is 0.05 wt % to 0.5 wt % with respect to the weight of the thermoelectric conversion material. The total oxygen content can be measured as described in “6. Measurement of total oxygen content”. The total oxygen content is expressed as a value after the sintering treatment, and even in a case where grains obtained in the process (a1) or (a2) are measured by the above method, a value that is substantially equal to that after the sintering treatment is obtained. However, in the case of the process (a2), measurement needs to be performed after a solvent adhering to a sample used is sufficiently dried and removed.

The grain size of the base phase material powder used in the process (a1) is not particularly limited as long as the surface can be oxidized to a desired degree, and is preferably 1 nm to 100 nm, and more preferably 1 nm to 50 nm. In a case where the grain size of the base phase material powder that is used is great, new surfaces are exposed and sequentially oxidized when the base phase material powders are mixed (crushed and mixed). Therefore, those skilled in the art can appropriately select mixing conditions to adjust the degree of oxidation by increasing the mixing time, or the like, depending on the grain size. Here, in a case where the powders are crushed during the mixing of the base phase material powders, the mixing time represents a time elapsed after the start of the mixing.

In the process (a1), the time for exposing the mixed base phase material powders to the low-oxygen atmosphere is not particularly limited as long as the surface can be oxidized to a desired degree, and is preferably 0.1 hour to 50 hours, and more preferably 0.5 hour to 3 hours. Here, the time represents a time elapsed after the start of the mixing.

The ratio of the elements constituting the base phase material powders used in the process (a1), is determined on the basis of the crystal system of a desired base phase material. For example, as described in Examples, to obtain a (Bi, Sb)₂Te₃ system, a molar ratio of Bi:Te:Sb is set to 8:32:60.

In the process (a1), the “low-oxygen atmosphere” means an oxidizing atmosphere in which only the surface of the base phase material powder is oxidized and the inside of the powder is maintained unoxidized. The concentration of oxygen in the low-oxygen atmosphere is not particularly limited as long as such conditions are satisfied, and specifically, is preferably 10 ppm to 10000 ppm, and more preferably 50 ppm to 100 ppm.

In the process (a1), the degree of oxidation of the elements constituting the base phase material may be appropriately adjusted by controlling conditions such as the mixing time.

The grain size of the base phase material powder used in the process (a2) is not particularly limited as long as the elements constituting the base phase material can be oxidized by alkoxylation to a desired degree, and from the viewpoint specific surface area, is more preferably 1 nm to 100 nm, and particularly preferably 1 nm to 50 nm.

Alcohol used in the process (a2) is not particularly limited as long as the elements constituting the base phase material can be alkoxylated, and specifically, may be one type or a mixture of two or more types selected from methanol, ethanol, propanol, butanol, pentanol, hexanol, heptanol, and octanol. Among these, from the viewpoint of molecular weight, ethanol, methanol, butanol, or the like is preferable.

In the process (a2), heating is preferably performed from the viewpoint of reaction rate. Specifically, heating is preferably performed at 40° C. to 80° C. In addition, it is preferable that the process (a2) is performed while stirring is performed from the viewpoint of homogeneity.

In the process (a2), the degree of oxidation of the elements constituting the base phase material can be appropriately adjusted by controlling conditions such as the mixing time, heating temperature, and stirring conditions.

<Alloying by Heat Treatment>

In the process (b), the elements constituting the base phase material are alloyed by performing a heat treatment on the powder obtained in the process (a1) or the solution obtained in (a2), thereby obtaining crystal grains. In this process, an oxide layer obtained in the process (a1) or (a2) exhibits the pinning effect as described above, and thus crystal coarsening is suppressed. Therefore, fine crystal grains of the base phase material are obtained. For example, a solution obtained by adding an appropriate solvent to the powder obtained in the process (a1) or the solution obtained in the process (a2) is subjected to a heat treatment in a sealed pressurization container, for example, a sealed autoclave, at a temperature of 150° C. to 450° C., preferably 180° C. to 400° C., and particularly preferably 200° C. to 350° C. so that the elements constituting the base phase material are alloyed. The heat treatment is preferably performed for 4 hours to 100 hours, and particularly preferably 10 hours to 48 hours. Thereafter, the resultant is dried, typically in a non-oxidizing atmosphere, for example, in an inert atmosphere, thereby obtaining a powdery thermoelectric conversion material.

In the manufacturing method, the processes (a) and (b) are continuously performed. Here, “continuously performed” means that the base phase material powders or the solution containing the base phase material powders is not exposed to an atmosphere (for example, air) having a higher oxygen concentration than the oxygen concentration in the low-oxygen atmosphere between the processes (a) and (b).

The thermoelectric conversion material obtained in the manufacturing method has advantages of low lattice thermal conductivity compared to a thermoelectric conversion material that is obtained by performing refining and oxidizing processes after an alloying process. Furthermore, according to the thermoelectric conversion material, the characteristics can be maintained even in long-term use at high temperatures.

In the manufacturing method, in a case where a bulk material needs to be obtained, the thermoelectric conversion material is subjected to spark plasma sintering (SPS) at a temperature of 300° C. to 500° C., thereby obtaining a thermoelectric conversion material bulk body. SPS may be performed by using an SPS machine equipped with punches (upper and lower), electrodes (upper and lower), a die, and a pressurizing device. In addition, during the sintering, only a sintering chamber of the sintering machine may be insulated from the outside air to be subjected to an inert sintering atmosphere, or the entire system may be enclosed by a housing to be subjected to an inert atmosphere.

A thermoelectric conversion device of the embodiment of the present invention can be obtained by using the thermoelectric conversion material of the embodiment of the present invention, and assembling an N-type nanocomposite thermoelectric conversion material, a P-type nanocomposite thermoelectric conversion material, an electrode, and an insulating substrate according to a well-known method.

Hereinafter, Examples of the present invention will be described, and the present invention is not limited to Examples.

### EXAMPLE 1-1

<Weak Oxidizing Treatment>

Powders of Bi, Te, and Sb nanoparticles (a primary particle size of about 10 nm) were weighed (a total amount of 10 g) to have a ratio of Bi:Te:Sb=8:32:60 in terms of molar ratio in a glovebox managed to 50 ppm to 100 ppm, were crushed and mixed, and were left for 1 hour.

<Alloying by Heat Treatment>

250 ml of ethanol and the powders were poured into an autoclave (pressure-resistant container), and were heated at 200° C. to 300° C. for 10 hours so that Bi, Te, and Sb are alloyed, thereby obtaining (Bi, Sb)₂Te₃ crystal grains. Next, the resultant was heated and dried in an N₂ gas flowing atmosphere such that the powder was recovered. At this time, about 10 g of the powder was recovered.

<Sintering>

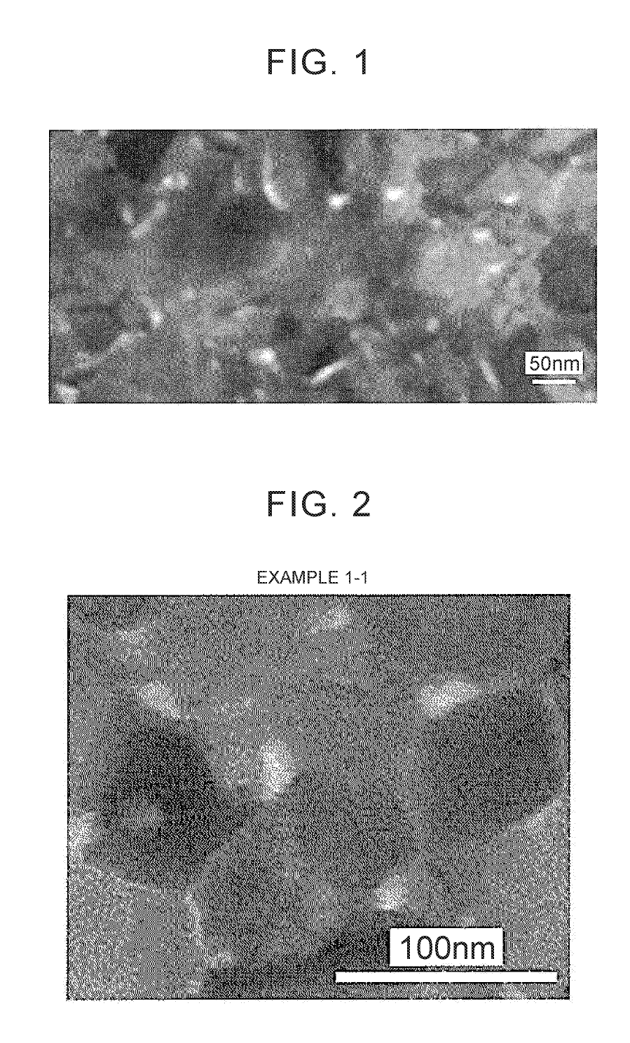

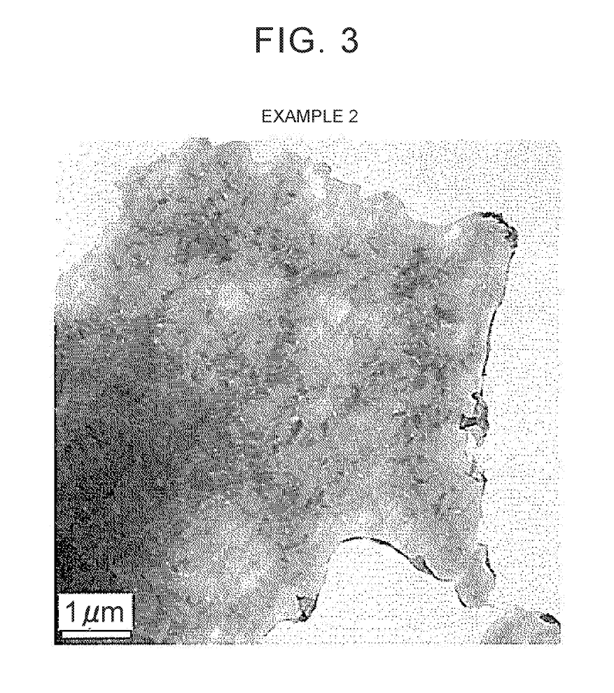

The recovered powder was subjected to spark plasma sintering (SPS) at 300° C. to 400° C., thereby obtaining a thermoelectric conversion material in which an oxide layer is formed in a layer shape on the surface of the crystal grains of the base material (matrix) formed from (Bi, Sb)₂Te₃ (FIGS. 1 and 2).

### EXAMPLE 1-2

A thermoelectric conversion material was obtained in the same manner as in Example 1-1.

### EXAMPLE 2

<Weak Oxidizing Treatment>

Powders of Bi, Te, and Sb nanoparticles (a primary particle size of about 10 nm) were weighed (a total amount of 10 g) to have a ratio of Bi:Te:Sb=8:32:60 in terms of molar ratio, were added to 400 ml of ethanol, and were stirred and mixed in a disperser at 60° C. for 2 hours.

<Alloying by Heat Treatment>

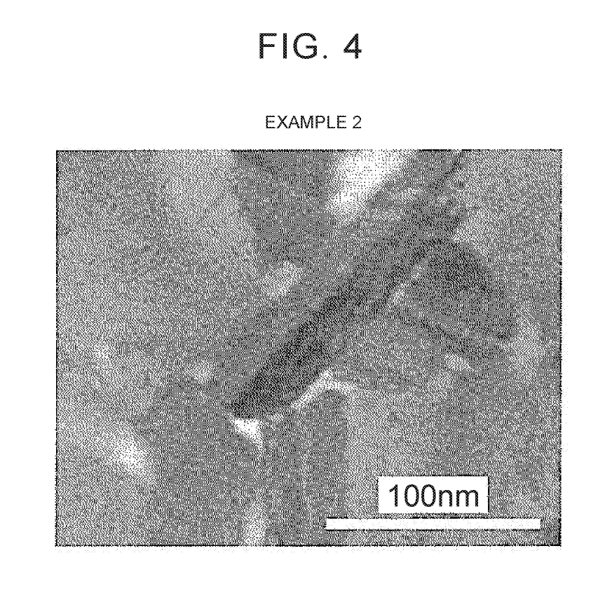

The obtained solution was poured into an autoclave (pressure-resistant container), and were heated at 200° C. to 300° C. for 10 hours so that Bi, Te, and Sb are alloyed, thereby obtaining (Bi, Sb)₂Te₃ crystal grains. Next, the resultant was heated and dried in an N₂ gas flowing atmosphere such that the powder was recovered. At this time, about 10 g of the powder was recovered (FIG. 3).

<Sintering>

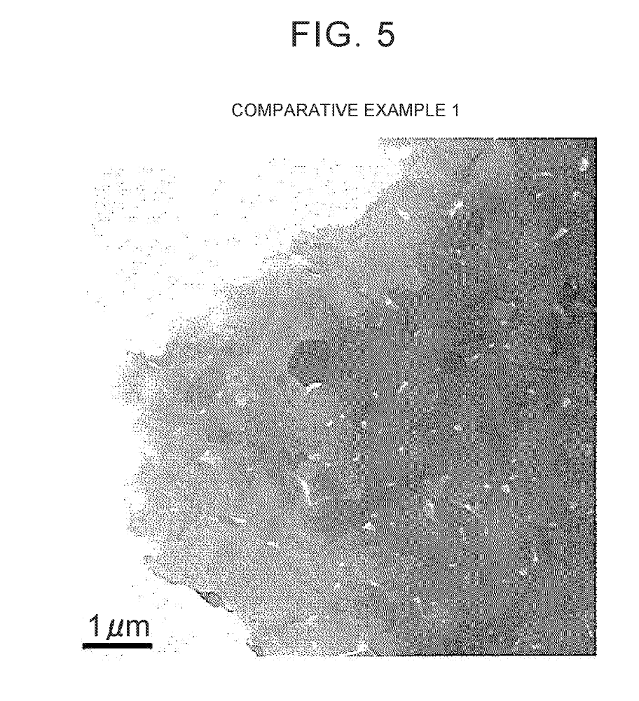

The recovered powder was subjected to spark plasma sintering (SPS) at 300° C. to 400° C., thereby obtaining a thermoelectric conversion material in which an oxide layer is formed in a layer shape on the surface of the crystal grains of the base material (matrix) formed from (Bi, Sb)₂Te₃ (FIG. 4).

### COMPARATIVE EXAMPLE 1

According to the following order and conditions, a (Bi, Sb)₂Te₃/(Bi, Sb, Te)Ox nanocomposite thermoelectric conversion material in which, in a (Bi, Sb)₂Te₃ thermoelectric conversion material matrix, phonon scattering particles formed from nanoparticles (Bi, Sb, Te)Ox of the oxide thereof are dispersed was manufactured.

<Synthesis of Nanoparticles of Constituent Elements Bi, Sb, and Te>

The constituent elements of the thermoelectric conversion material matrix were dissolved in ethanol as chloride BiCl₃, TeCl₄, and SbCl₃, and an ethanol solution of sodium borohydride (NaBH₄) as a reducing agent was dropped, thereby synthesizing metal nanoparticles of Bi, Te, and Sb. The ethanol slurry containing the obtained nanoparticles was filtered and cleaned by a solution of 500 mL of water and 300 mL of ethanol to remove impurities, and thereafter filtered and cleaned by 300 mL of ethanol.

<Hydrothermal Treatment+Oxidizing Treatment>

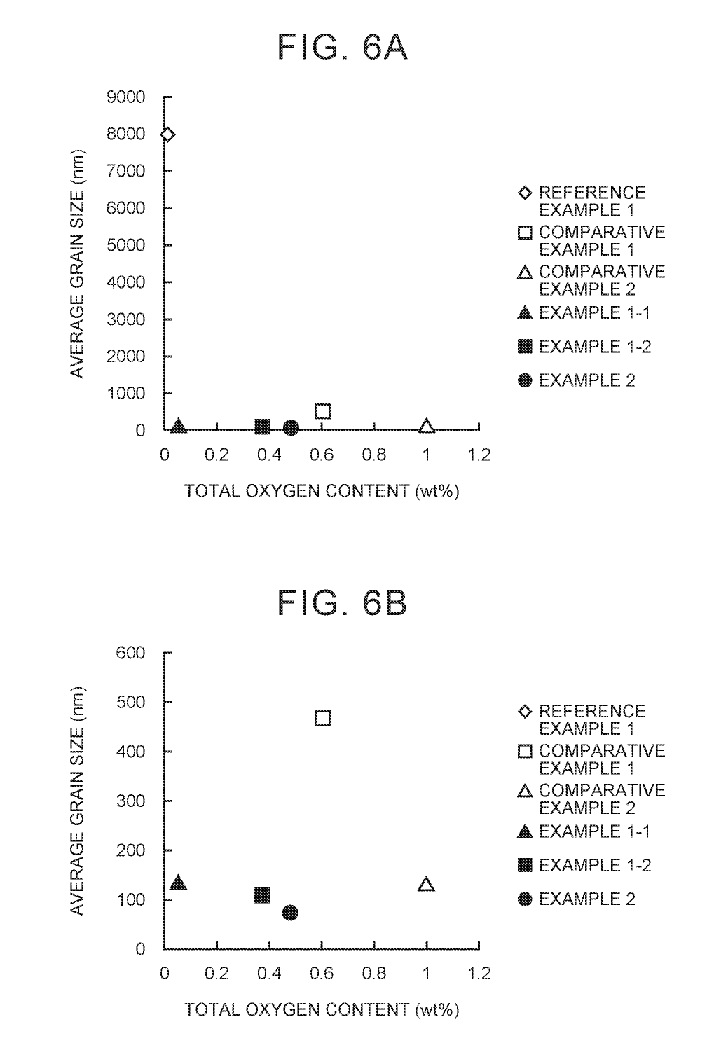

Next, the resultant was put into a sealed autoclave, and subjected to a hydrothermal treatment of 300° C.×1 h in water, thereby producing (Bi, Sb)₂Te₃ alloy particles for the matrix. At the same time, an oxide layer was formed on the surface of the produced (Bi, Sb)₂Te₃ alloy particles for the matrix. After the hydrothermal treatment, the resultant was dried in an N₂ gas flowing atmosphere such that the powder was recovered. At this time, about 2 g of the powder was recovered (FIG. 5).

<Sintering>

The recovered powder was subjected to spark plasma sintering (SPS) of 380° C.×5 min, thereby obtaining a bulk body of a (Bi, Sb)₂Te₃/(Bi, Sb, Te)Ox nanocomposite thermoelectric conversion material. At this time, since the sintering was performed through the spark plasma sintering, the oxide layer on the surface of the (Bi, Sb)₂Te₃ alloy particles was partially broken, and thus a conducting path was formed. A thermoelectric conversion material was obtained as described above.

### COMPARATIVE EXAMPLE 2

<Preparation of Raw Material Solution>

A raw material solution was prepared by dissolving a raw material in 100 ml of ethanol as described below.

Base phase raw material: bismuth chloride (BiCl₃) 0.4 g,

Tellurium chloride (TeCl₄) 2.56 g,

Antimony chloride (SbCl₃) 1.16 g,

Insulating raw material:tetraethoxysilane (TEOS:Si(OC₂H₅)₄) 0.23 g

<Reduction and Addition of Basic Compound>

A solution in which 2.4 g of NaBH₄ as a reducing agent was dissolved in 100 ml of methanol was dropped onto the raw material solution. To the slurry containing nanoparticles precipitated through the reduction, a solution in which 0.004 g of sodium hydroxide as a basic compound was dissolved in 10 ml of water was added and mixed. The obtained slurry was filtered and cleaned by 500 ml of water, and was further filtered and cleaned by 300 ml of ethanol.

<Heat Treatment>

Thereafter, the resultant was poured into a sealed autoclave, and subjected to a hydrothermal treatment of 240° C.×48 h, thereby alloying the matrix. Next, the resultant was dried in an N₂ gas flowing atmosphere such that the powder was recovered. At this time, about 1.5 g of the powder was recovered.

<Sintering>

The recovered powder was subjected to spark plasma sintering (SPS) at 360° C., thereby obtaining a thermoelectric conversion material in which silicon oxides are formed in a layer shape at the interface between the crystal grains of the base material (matrix) formed from (Bi, Sb)₂Te₃.

The thermoelectric conversion materials of Example 1-2 and Comparative Example 1-2 were evaluated by a method described below.

1. TEM Sample Production

A sintered body having a diameter of 10 mm×1 to 2 mm was cut into 1 to 2 mm×1 to 2 mm by IsoMet. Thereafter, mechanical polishing was performed until a thickness of 100 μm or smaller was achieved, thereby producing a sample. Thereafter, the sample was attached to a Cu mesh for TEM using an adhesive (trade name: Araldite) and dried. Next, a portion of the resultant was subjected to mechanical polishing by Dimple Grinder (manufactured by Gatan Inc.) until a thickness of 20 μm or smaller was achieved. Thereafter, the resultant was formed to a thin piece by using Ar ion milling (manufactured by Gatan Inc.) until the thinned portion achieves a thickness of 10 nm to 100 nm.

2. TEM Observation

TEM observation was performed on the portion having a thickness of 100 nm or smaller in the sample manufacturing process. TEM observation conditions are as follows.

Model of apparatus: Tecnai G2 S-Twin TEM (manufactured by FEI Company) with an acceleration voltage of 300 kV 3. Measurement of Grain Size of Crystals of Base Phase Material

The grain sizes of about 500 to 700 crystals were measured through TEM, and the average value thereof was used as an average crystal grain size.

4. Measurement of Thickness, Minor Axis r, and Major Axis R of Oxide Layer

Measurement was performed on the oxide layers of about 500 to 700 crystals through TEM, and the average value thereof was calculated.

5. Measurement of Lattice Thermal Conductivity

Measurement was based on a steady state method thermal conductivity measurement method and a flash method (non-steady method) (a flash method thermal conductivity measuring apparatus manufactured by NETZSCH). The lattice thermal conductivity was calculated by subtracting a carrier thermal conductivity ((Kel) from the thermal conductivity of the entirety.

Kel=LσT

(L is the Lorentz number, σ is the electrical conductivity (=1/specific resistance), and

T is the absolute temperature).

6. Measurement of Total Oxygen Content

The total oxygen content was measured by a combustion method. The thermoelectric conversion material was heated, and the amounts of carbon dioxide and oxygen generated during the heating were measured.

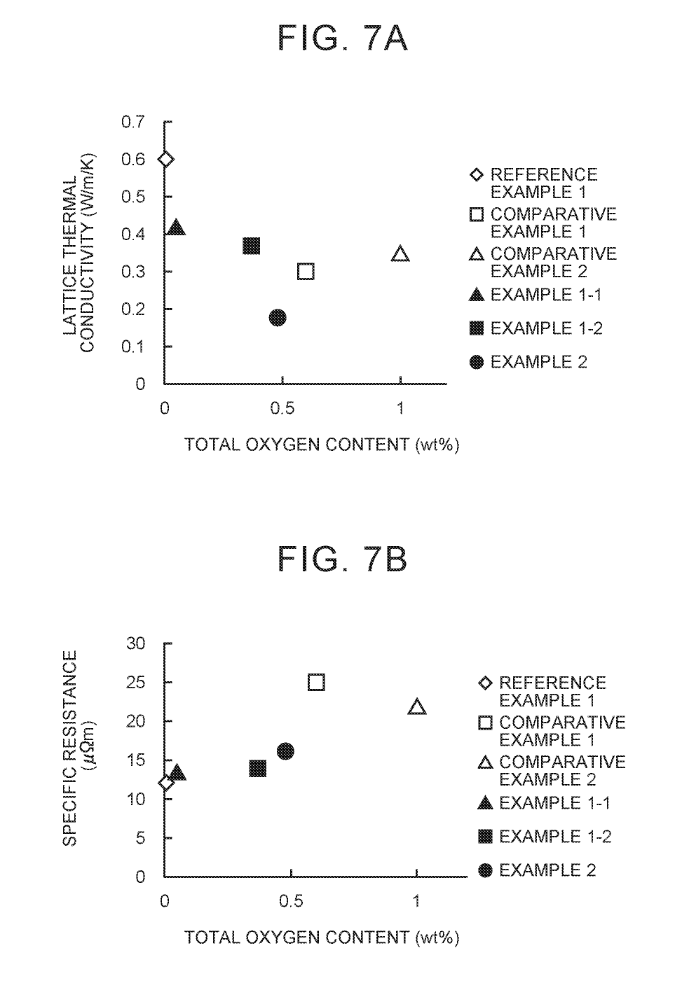

FIG. 6A shows the relationship between the total oxygen content of the thermoelectric conversion materials of Examples 1 and 2 and Comparative Examples 1 and 2 and Reference Example 1 (corresponding to Example 1 of JP 2001-250990 A) and the average grain size of crystal grains (average crystal grain size) of the base phase material thereof. FIG. 6B is an enlarged graph of a portion of FIG. 6A. From FIGS. 6A and 6B, it can be seen that the thermoelectric conversion materials of Examples 1 and 2 has a tendency toward a smaller average crystal grain size even though the oxygen amount was less than that of a thermoelectric conversion material according to the related art. In the thermoelectric conversion materials of Examples 1 and 2, the average grain size of crystal grains of the base phase material was smaller than that of the thermoelectric conversion material of Comparative Example 1 in which alloying and oxidation of the base phase material were simultaneously performed. It is seen that in a case where alloying and oxidation of the base phase material are simultaneously performed by performing a hydrothermal treatment in water as in Comparative Example 1, an action of interrupting coarsening of the grain size of the base phase material due to the oxides is insufficient. In addition, in the thermoelectric conversion materials of Examples 1 and 2, the total oxygen content was smaller than that of the thermoelectric conversion material of Comparative Example 2 in which coarsening of the grain size was achieved by the oxides by mixing Si oxides in advance. It is seen that when the Si oxides are used as in Comparative Example 2, it is difficult to reduce the oxygen amount.

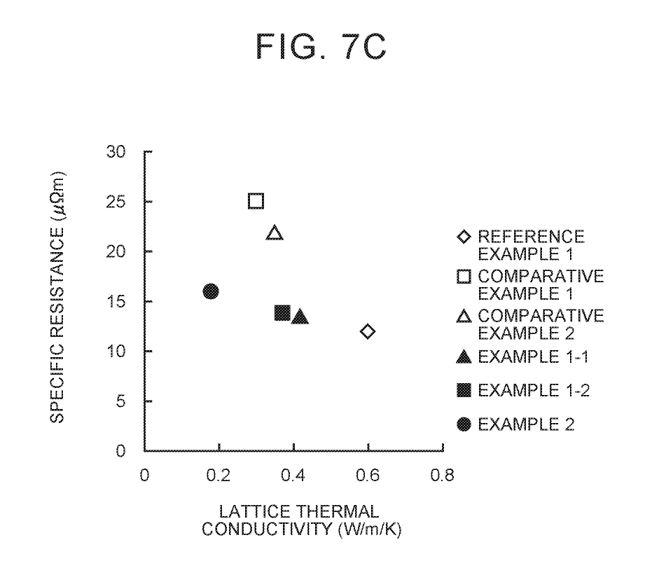

FIGS. 7A and 7B show the relationship between the total oxygen contents of the thermoelectric conversion materials of Examples 1 and 2 and Comparative Examples 1 and 2, and the thermoelectric conversion material of Reference Example 1, and the lattice thermal conductivity thereof, and the relationship between the total oxygen content and the specific resistance thereof. FIG. 7C shows the relationship between the lattice thermal conductivity and the specific resistance of the thermoelectric conversion materials of Examples 1 and 2 and Comparative Examples 1 and 2, and the thermoelectric conversion material of Reference Example 1. From FIGS. 7A to 7C, it is seen that in the thermoelectric conversion materials of Examples 1 and 2, an increase in the electrical resistance is suppressed and the thermal conductivity is sufficiently reduced. It is seen that the thermoelectric conversion material of Comparative Example 1 in which an action of interrupting coarsening of the grain size due to the oxides is insufficient, the electrical resistance is high. In addition, it is seen that in the thermoelectric conversion material of Comparative Example 2 in which a reduction in oxygen amount is insufficient, the electrical resistance is high.

A thermoelectric conversion device which uses the nanocomposite thermoelectric conversion material of the present invention can be used for power generation using the exhaust heat of a vehicle or geothermal heat, or for the power supply for a satellite. In addition, a thermoelectric conversion device which uses the nanocomposite thermoelectric conversion material of the present invention can be used for a temperature control device of an electronic appliance or a vehicle.

What is claimed is:

1. A BiTe-based or CoSb₃-based thermoelectric conversion material, comprising:
a base phase material in which an oxide layer is formed on a surface of the base phase,
wherein the thermoelectric conversion material is manufactured by a method including
(a) a weak oxidizing process selected from
(a1) mixing base phase material powders under a low-oxygen atmosphere and thereafter exposing the base phase material powders to the low-oxygen atmosphere, and
(a2) impregnating base phase material powders with alcohol, and
(b) an alloying process of performing a heat treatment on a powder obtained in the process (a1) or a solution obtained in (a2), and
the processes (a) and (b) are continuously performed.

2. The thermoelectric conversion material according to claim 1, wherein
an average grain size of crystal grains of the base phase material is 400 nm or smaller,
a thickness of the oxide layer is 0.1 nm to 10 nm,
the oxide layer has an average minor axis r of 2 nm to 15 nm and an average major axis R of 10 nm to 500 nm, and
r and R satisfy an expression: r≦R.

3. The thermoelectric conversion material according to claim 1, wherein
a total oxygen content of the thermoelectric conversion material is 0.05 wt % to 0.5 wt % with respect to a weight of the thermoelectric conversion material.

4. A manufacturing method of a BiTe-based or CoSb₃-based thermoelectric conversion material, the manufacturing method comprising:
(a) a weak oxidizing process selected from
(a1) mixing base phase material powders under a low-oxygen atmosphere and thereafter exposing the base phase material powders to the low-oxygen atmosphere, and
(a2) impregnating base phase material powders with alcohol; and
(b) an alloying process of performing a heat treatment on a powder obtained in the process (a1) or a solution obtained in (a2),
wherein the processes (a) and (b) are continuously performed.

5. A thermoelectric conversion device using the thermoelectric conversion material according to claim 1.
